(19) United States
(12) Patent Application Publication
(10) Pub. No.: US 2025/0373026 A1
(43) Pub. Date: Dec. 4, 2025

(54) COMMUNICATION DEVICE, COMMUNICATION METHOD, AND POWER STORAGE SYSTEM

(71) Applicant: YAZAKI CORPORATION, Tokyo (JP)

(72) Inventor: Masaya Hatakeyama, Susono-shi (JP)

(21) Appl. No.: 19/299,303

(22) Filed: Aug. 13, 2025

Related U.S. Application Data
(63) Continuation of application No. PCT/JP2024/004100, filed on Feb. 7, 2024.

(30) Foreign Application Priority Data
Feb. 28, 2023 (JP) 2023-030008

(51) Int. Cl. H02J 7/00; G01R 31/371

(52) U.S. Cl. CPC H02J 7/00032; G01R 31/371; H02J 7/005

(57) ABSTRACT

A communication device executes a state information transmission process of transmitting a plurality of types of battery state information from a battery to a BMS via serial communication. The state information transmission process includes: a process of transmitting a frame including the plurality of types of battery state information from the battery; a process of replacing an order of the plurality of types of battery state information in the frame transmitted from the battery with a predetermined order common to other frames; a process of assigning battery No. information to the frame in which the order of the plurality of types of battery state information is replaced with the predetermined order; and a process of transmitting, to the BMS, the frame in which the order of the plurality of types of battery state information is replaced with the predetermined order and to which the battery No. information is assigned.

### CROSS-REFERENCE TO RELATED APPLICATIONS

This is a continuation of International Application No. PCT/JP2024/004100 filed on Feb. 7, 2024, and claims priority from Japanese Patent Application No. 2023-030008 filed on Feb. 28, 2023, the entire content of which is incorporated herein by reference.

### TECHNICAL FIELD

The present invention relates to a communication device, a communication method, and a power storage system.

### BACKGROUND ART

There is known a system that collects information about a state of a battery (hereinafter, referred to as state information) and remotely monitors the battery (for example, see Patent Literature 1). The system disclosed in Patent Literature 1 includes various sensors such as a voltage sensor, a current sensor, and a temperature sensor for detecting a state of a battery, a controller to which detection signals of the sensors are input, and a communication interface for communicating state information and the like of the battery input to the controller.

### CITATION LIST

### Patent Literature

Patent Literature 1: JP2020-530256A

### SUMMARY OF INVENTION

### Technical Problem

It is assumed that a power storage system is implemented by using storage batteries used in an electric automatic vehicle or storage batteries unused for the electric automatic vehicle and a communication module for the electric automatic vehicle that transmits a plurality of types of battery state information in accordance with a predetermined serial communication protocol such as a universal asynchronous receiver/transmitter (UART). In this assumption, when the plurality of storage batteries are used in different vehicle models or prepared for different vehicle models, it is assumed that orders of serial data transmitted from a plurality of communication modules are different from one another. For example, it is assumed that a frame of a UART for a certain vehicle model is designed so that serial data is arranged in an order of voltage, current, and SOC, and a frame of a UART for another vehicle model is designed so that the serial data is arranged in an order of SOC, voltage, and current. In this case, there is a possibility that a state monitoring device cannot acquire a plurality of types of state information about the plurality of storage batteries.

In view of the above circumstances, an object of the present invention is to provide a communication device, a communication method, and a power storage system in which a plurality of types of state information are transmitted from a plurality of storage batteries to a state monitoring device via serial communication, so that the state monitoring device can acquire the plurality of types of state information about the plurality of storage batteries.

### Solution to Problem

A communication device of the present invention is a communication device that is provided in a power storage system including a plurality of storage batteries and a state monitoring device configured to monitor states of the plurality of storage batteries based on state information that is information about the states of the storage batteries transmitted from the storage batteries, and that executes a state information transmission process of transmitting a plurality of types of the state information from the storage batteries to the state monitoring device via serial communication, in which the state information transmission process includes: a process of transmitting a first frame including the plurality of types of state information from the storage batteries; a process of replacing an order of the plurality of types of state information in the first frame transmitted from the storage batteries with a predetermined order common to other first frames; a process of assigning storage battery identification information for identifying the storage batteries to the first frame in which the order of the plurality of types of state information is replaced with the predetermined order; and a process of transmitting, to the state monitoring device, the first frame in which the order of the plurality of types of state information is replaced with the predetermined order and to which the storage battery identification information is assigned.

A communication method of the present invention is a communication method for transmitting, in a power storage system including a plurality of storage batteries and a state monitoring device configured to monitor states of the plurality of storage batteries based on state information that is information about the states of the storage batteries transmitted from the storage batteries, a plurality of types of the state information from the storage batteries to the state monitoring device via serial communication, the communication method including: a step of transmitting a frame including the plurality of types of state information from the storage batteries; a step of replacing an order of the plurality of types of state information in the frame transmitted from the storage batteries with a predetermined order common to other frames; a step of assigning storage battery identification information for identifying the storage batteries to the frame in which the order of the plurality of types of state information is replaced with the predetermined order; and a step of transmitting, to the state monitoring device, the frame in which the order of the plurality of types of state information is replaced with the predetermined order and to which the storage battery identification information is assigned.

A power storage system of the present invention is a power storage system including: a plurality of storage batteries; a state monitoring device configured to monitor states of the plurality of storage batteries based on state information that is information about the states of the storage batteries transmitted from the storage batteries; and a communication device configured to transmit a plurality of types of the state information from the storage batteries to the state monitoring device via serial communication, in which the communication device is configured to execute: a process of transmitting a frame including the plurality of types of state information from the storage batteries; a process of replacing an order of the plurality of types of state information in the frame transmitted from the storage batteries with a predetermined order common to other frames; a process of assigning storage battery identification information for identifying the storage batteries to the frame in which the order of the plurality of types of state information is replaced with the predetermined order; and a process of transmitting, to the state monitoring device, the frame in which the order of the plurality of types of state information is replaced with the predetermined order and to which the storage battery identification information is assigned.

### Advantageous Effects of Invention

According to the present invention, in the power storage system in which the plurality of types of state information are transmitted from the plurality of storage batteries to the state monitoring device via serial communication, the state monitoring device can acquire the plurality of types of state information about the plurality of storage batteries.

### BRIEF DESCRIPTION OF DRAWINGS

FIG. 1 is a circuit diagram illustrating a circuit configuration of a power storage system including a communication device according to an embodiment of the present invention.

FIG. 2 is a functional block diagram illustrating an example of functions implemented by the communication device illustrated in FIG. 1.

FIG. 3 is a table illustrating an example of a configuration of a frame of serial data transmitted from a battery.

FIG. 4 is a table illustrating an example of frame replacement information illustrated in FIG. 2.

FIG. 5 is a diagram illustrating an example of a procedure for replacing an order of a plurality of types of serial data in a frame and assigning battery No. information to the frame.

FIG. 6 is a diagram illustrating an example of a procedure for replacing an order of a plurality of types of serial data in a frame and assigning battery No. information to the frame.

FIG. 7 is a flowchart illustrating an example of a procedure for updating frame replacement information.

FIG. 8 is a flowchart illustrating communication between a battery and a BMS.

### DESCRIPTION OF EMBODIMENTS

Hereinafter, the present invention will be described with reference to preferred embodiments. The present invention is not limited to the embodiments to be described below, and the embodiments can be appropriately modified without departing from the gist of the present invention. In the embodiments to be described below, a part of configurations may be not described or illustrated in the drawings, and regarding details of the omitted techniques, publicly known or well-known techniques will be appropriately applied as long as there is no contradiction with the contents to be described below.

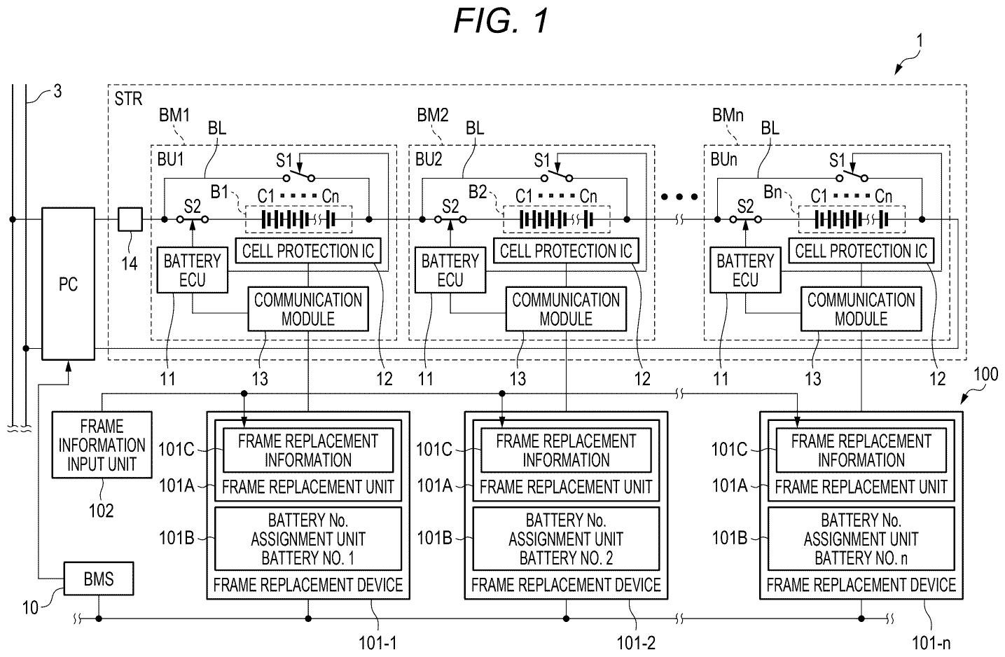

FIG. 1 is a circuit diagram illustrating a circuit configuration of a power storage system 1 including a communication device 100 according to an embodiment of the present invention. The power storage system 1 illustrated in FIG. 1 is a stationary or in-vehicle power supply, and includes a plurality of strings STR or a single string STR, a power converter PC, and a battery management system (BMS) 10. When there are a plurality of strings STR, the plurality of strings STR are connected in parallel.

The string STR includes a plurality of batteries B1 to Bn connected in series. Each of the batteries B1 to Bn includes a plurality of cells C1 to Cn connected in series. The batteries B1 to Bn of the present embodiment are used in an electric automatic vehicle and collected, or are prepared for the electric automatic vehicle and are unused. Therefore, there may be differences in a degree of deterioration among the batteries B1 to Bn. The batteries B1 to Bn are lithium ion batteries or the like, and are discharged through the power converter PC (to be described later) to supply power to an external system (not illustrated). The external system includes a load, a power generator, and the like. When the power storage system 1 is a stationary power supply, home appliances, a commercial power supply system, and the like serve as loads, and a solar photovoltaic power generation system and the like serve as a power generator. On the other hand, when the power storage system 1 is an in-vehicle power supply, a driving motor, an air conditioner, various in-vehicle electrical components, and the like serve as loads. The driving motor serves as both a load and a power generator. On the other hand, power generated by the power generator is supplied to the batteries B1 to Bn through the power converter PC, and the batteries B1 to Bn are charged.

The string STR includes a plurality of battery modules BM1 to BMn and a current sensor 14. The battery modules BM1 to BMn include batteries B1 to Bn, battery electronic control units (ECUs) 11, cell protection integrated circuits (ICs) 12, communication modules 13, and bypass units BU1 to BUn, respectively. The batteries B1 to Bn, the cell protection ICs 12, and the communication modules 13 are used in an electric automatic vehicle and collected, or are prepared for the electric automatic vehicle and unused.

The battery ECUs 11 detect states of the batteries B1 to Bn, determine the states of the batteries B1 to Bn, and control the bypass units BU1 to BUn. The cell protection IC 12 detects overcharge, overdischarge, discharge overcurrent, and charge overcurrent of the cells C1 to Cn, detects and interrupts a short-circuit current, detects a disconnection, recovers the cells C1 to Cn from an overcharged state or an overdischarged state, and balances the cells C1 to Cn.

The battery ECUs 11 transmit information about the states of the batteries B1 to Bn (hereinafter referred to as battery state information) to the communication modules 13. On the other hand, the battery ECUs 11 receive information about the control of the batteries B1 to Bn (hereinafter referred to as battery control information) from the communication modules 13. Examples of the battery state information transmitted from the battery ECUs 11 include a state of charge (SOC). In addition, examples of the battery control information received by the battery ECUs 11 include a voltage instruction value, a current instruction value, and the control information (ON/OFF of switches S1 and S2 to be described later) of the bypass units BU1 to BUn.

The cell protection IC 12 transmits the battery state information to the communication module 13 and receives the battery control information from the communication module 13. Examples of the battery state information transmitted from the cell protection ICs 12 include voltages of the cells C1 to Cn, and a current of the batteries B1 to Bn. In addition, examples of the battery control information received by the cell protection ICs 12 include a voltage instruction value and a current instruction value.

The communication module 13 transmits the battery state information to the BMS 10 in accordance with a serial communication protocol such as a UART by the communication device 100, and receives the battery control information from the BMS 10. The communication device 100 will be described later.

The power converter PC is a bidirectional converter and is connected to a string bus 3. In addition, the power converter PC is connected to a positive electrode of the starting battery B1 and a negative electrode of the ending battery Bn.

When the string STR is charged, the power converter PC converts a voltage input from the string bus 3 according to an instruction value of charge power (or charge current) and outputs the converted voltage to the plurality of batteries B1 to Bn. Here, the voltage on the string STR changes according to a bypass state of the batteries B1 to Bn (number of bypassed batteries B1 to Bn) and a charging state of the batteries B1 to Bn. Therefore, when the string STR is charged, the power converter PC converts the voltage input from the string bus 3 into the voltage on the string STR and outputs the converted voltage to the plurality of batteries B1 to Bn.

When the string STR is discharged, the power converter PC converts the voltage input from the plurality of batteries B1 to Bn according to an instruction value of discharge power (or discharge current) and outputs the converted voltage to the string bus 3. Here, the input voltage of the power converter PC during discharge changes according to the bypass state of the batteries B1 to Bn or the charging state of the batteries B1 to Bn. Accordingly, when the plurality of strings STR are operated in parallel, variations occur in the input voltage of the power converter PC among the strings STR during discharge. Therefore, when the string STR is discharged, the power converter PC converts the input voltage into a voltage that matches the other strings STR and outputs the converted voltage to the string bus 3. When the current flowing through the string bus 3 is an alternating current, the power converter PC includes a synchronization unit for following a change in an instantaneous value.

The bypass units BU1 to BUn are provided for the batteries B1 to Bn, respectively. Each of the bypass units BU1 to BUn includes a bypass line BL and the switches S1 and S2. The bypass line BL is a power line that bypasses each of the batteries B1 to Bn. The switch S1 is provided on the bypass line BL. The switch S1 is, for example, a mechanical switch, a semiconductor switch, or a relay. The switch S2 is provided between a positive electrode of each of the batteries B1 to Bn and one end of the bypass line BL. The switch S2 is, for example, a mechanical switch, a semiconductor switch, or a relay.

The starting battery B1 and the ending battery Bn are connected to an external system via the power converter PC and the string bus 3. When the switch S1 is turned off and the switch S2 is turned on in all the bypass units BU1 to BUn, all the batteries B1 to Bn are connected in series. On the other hand, when the switch S2 is turned off and the switch S1 is turned on in any one of the bypass units BU1 to BUn, the batteries B1 to Bn corresponding to the bypass units BU1 to BUn are bypassed.

The current sensor 14 is provided on the power line of the string STR. The current sensor 14 detects a charge and discharge current of the string STR and transmits a detection signal to the BMS 10. In addition, the string STR is provided with a voltage sensor, a temperature sensor, and the like (not illustrated). The voltage sensor detects a total voltage of the string STR and transmits a detection signal to the BMS 10. In addition, the temperature sensor detects an ambient temperature of the string STR and transmits a detection signal to the BMS 10.

The BMS 10 communicates with a host controller (not illustrated), the plurality of battery ECUs 11, and the plurality of cell protection ICs 12, and controls and manages the plurality of battery modules BM1 to BMn. In addition, the BMS 10 controls and manages auxiliary equipment provided in the string STR. Examples of the auxiliary equipment include the power converter PC and the current sensor 14.

Based on the battery state information received from the battery ECUs 11 and the cell protection ICs 12, the BMS 10 monitors the states of the batteries B1 to Bn and generates and transmits the battery control information. The battery control information includes information about the control of the bypass units BU1 to BUn, and information about voltage instruction values and current instruction values of the batteries B1 to Bn. Here, the BMS 10 receives an instruction value for charge and discharge power (or charge and discharge current) of the string STR from the host controller, and calculates the voltage instruction values and the current instruction values of the batteries B1 to Bn based on the instruction value for the charge and discharge power and the state information of the batteries B1 to Bn. In addition, the BMS 10 determines whether a request for the control of the bypass units BU1 to BUn transmitted from the battery ECUs 11 is permitted, and transmits bypass control information according to the determination result to the battery ECUs 11.

The communication device 100 includes a plurality of frame replacement devices 101-1 to 101-n and a frame information input unit 102. The frame replacement devices 101-1 to 101-n are provided for the respective battery modules BM1 to BMn. It is not essential to provide the plurality of frame replacement devices 101-1 to 101-n and make the frame replacement devices 101-1 to 101-n correspond to the battery modules BM1 to BMn in a one-to-one manner. One frame replacement device may be provided with a plurality of input and output terminals, and the input and output terminals may correspond to the battery modules BM1 to BMn in a one-to-one manner.

Each of the frame replacement devices 101-1 to 101-n includes a frame replacement unit 101A and a battery No. assignment unit 101B. The frame replacement unit 101A stores frame replacement information 101C. The frame replacement information 101C includes information on a frame defined for each of the battery modules BM1 to BMn and information on a frame defined for transmission and reception of the BMS 10. The information on the frame includes information on an order of a plurality of types of serial data in the frame. The information on the frame defined for each of the battery modules BM1 to BMn is manually input from the frame information input unit 102 to the frame replacement information 101C.

Here, the order of the plurality of types of serial data in the frame defined for the transmission and reception of the BMS 10 and an order of a plurality of types of serial data in the frame defined for each of the battery modules BM1 to BMn have a one-to-other relation. That is, the order of the plurality of types of serial data in the frame defined for the transmission and reception of the BMS 10 is a predetermined order common to the plurality of battery modules BM1 to BMn.

When the plurality of types of serial data are transmitted from the communication module 13, the frame replacement unit 101A replaces the order of the plurality of types of serial data in the frame with the predetermined order with reference to the frame replacement information 101C. Then, the frame replacement unit 101A transmits the plurality of types of serial data after being replaced in the predetermined order to the battery No. assignment unit 101B. On the other hand, when the plurality of types of serial data are transmitted from the battery No. assignment unit 101B, the frame replacement unit 101A replaces the order of the plurality of types of serial data in the frame with reference to the frame replacement information 101C. At this time, the order of the plurality of types of serial data is replaced from the above predetermined order to the order defined for each of the battery modules BM1 to BMn. Then, the frame replacement unit 101A transmits the plurality of types of serial data after the order is replaced to the communication module 13.

The battery No. assignment unit 101B stores battery No. information for identifying each of the batteries B1 to Bn. When the plurality of types of serial data are transmitted from the frame replacement unit 101A, the battery No. assignment unit 101B assigns a battery No. to the frame. Then, the battery No. assignment unit 101B transmits, to the BMS 10, a frame including the battery No. and the plurality of types of serial data after being replaced in the predetermined order. In addition, when the plurality of types of serial data and the battery No. are transmitted from the BMS 10, the battery No. assignment unit 101B removes the battery No. from the frame. Then, the battery No. assignment unit 101B transmits, to the frame replacement unit 101A, the plurality of types of serial data in which the battery No. is removed from the frame.

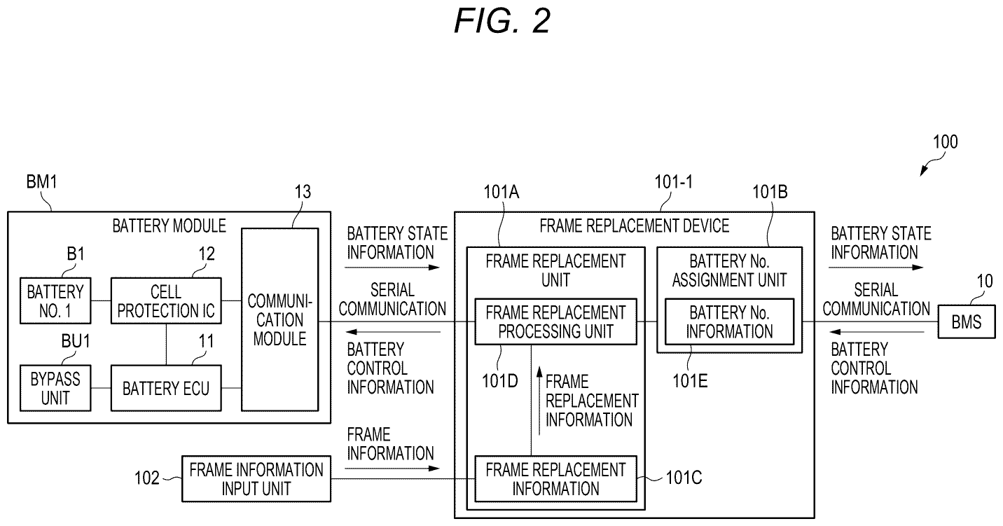

FIG. 2 is a functional block diagram illustrating an example of functions implemented by the communication device 100 illustrated in FIG. 1. FIG. 2 illustrates communication between the battery module BM1 and the BMS 10, and communication between the other battery modules BM2 to BMn and the BMS 10 is also performed in a similar manner.

The frame replacement device 101-1 illustrated in FIG. 2 is installed in advance between the battery module BM1 and the BMS 10 before the battery B1 is newly connected to the power storage system 1 (see FIG. 1). Here, in the present embodiment, the battery B1, the cell protection IC 12, and the communication module 13 are used in the electric automatic vehicle or prepared for the electric automatic vehicle.

In contrast, the bypass unit BU1, the battery ECU 11, and the frame replacement device 101-1 are newly installed. When the battery module BM1 including the bypass unit BU1 is used, the bypass unit BU1 may also be used. In addition, when the battery ECU 11 can be reused, there is no need to newly install the bypass unit BU1, the battery ECU 11, and the frame replacement device 101-1.

As illustrated in FIG. 2, the battery state information is transmitted as serial data from the communication module 13 to the frame replacement device 101-1. Here, a plurality of types of battery state information such as voltage, current, and SOC are transmitted as a plurality of types of serial data from the communication module 13 to the frame replacement device 101-1. The plurality of types of serial data are arranged in a frame designed in accordance with a serial communication protocol in a predetermined order.

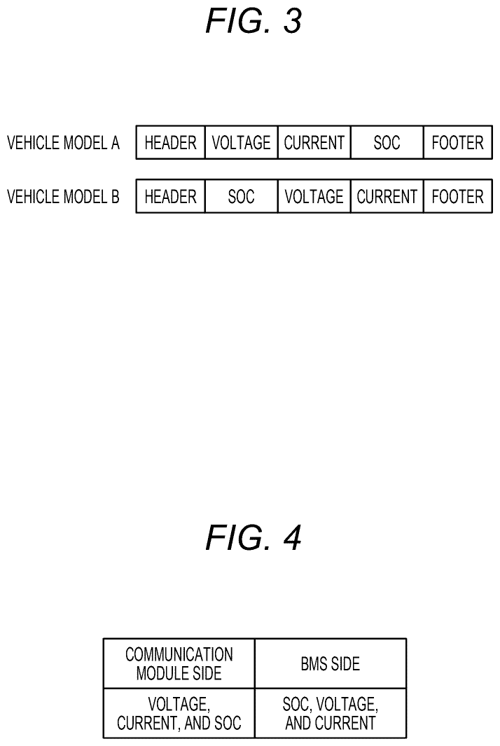

FIG. 3 is a table illustrating an example of a configuration of a frame of serial data transmitted from the battery B1. As illustrated in the table, the frame of the serial data transmitted from the communication module 13 includes a header, a plurality of types of serial data, and a footer. In a case of the UART, the frame includes a command, a data length for each command, a cyclic redundancy check (CRC), and the like, in addition to the header, the serial data, and the footer. In addition, in the UART, the header and the footer are unique identifiers for determining whether communication with an appropriate device is being made. In the UART, the footer is called a trailer and is added to the end of the serial data.

Here, the batteries B1 to Bn that are used in the electric automatic vehicle or are unused for the electric automatic vehicle, and the communication modules 13 for the electric automatic vehicle that transmits the plurality of types of battery state information via serial communication are utilized in the power storage system 1 of the present embodiment. In the power storage system 1, the plurality of batteries B1 to Bn are used in different vehicle models or are prepared for different vehicle models. In such a case, it is assumed that the orders of the plurality of types of serial data transmitted from the plurality of communication modules 13 are different from one another. For example, as illustrated in FIG. 3, a frame of serial data for a vehicle model A is designed so that the serial data continues in an order of voltage, current, and SOC. In contrast, a frame of serial data for a vehicle model B is designed so that the serial data continues in an order of SOC, voltage, and current. Therefore, there is a possibility that the BMS 10 cannot acquire the plurality of types of battery state information for the plurality of batteries B1 to Bn.

Therefore, in the present embodiment, a frame replacement processing unit 101D (see FIG. 2) of each of the frame replacement devices 101-1 to 101-n replaces the order of the plurality of types of serial data in the frame transmitted from each of the batteries B1 to Bn with the above predetermined order with reference to the frame replacement information 101C.

FIG. 4 is a table illustrating an example of the frame replacement information 101C illustrated in FIG. 2. As illustrated in the table, the frame replacement information 101C is a table indicating a relation between an order of the plurality of types of battery state information transmitted from the communication module 13 and an order of the plurality of types of battery state information transmitted to the BMS 10. The order of the plurality of types of serial data transmitted from the communication module 13 is manually input from the frame information input unit 102 and registered in the frame replacement information 101C. On the other hand, the order of the plurality of types of battery state information transmitted to the BMS 10 corresponds to the above predetermined order, is common to the plurality of frame replacement devices 101-1 to 101-n, and is registered in the frame replacement information 101C in advance.

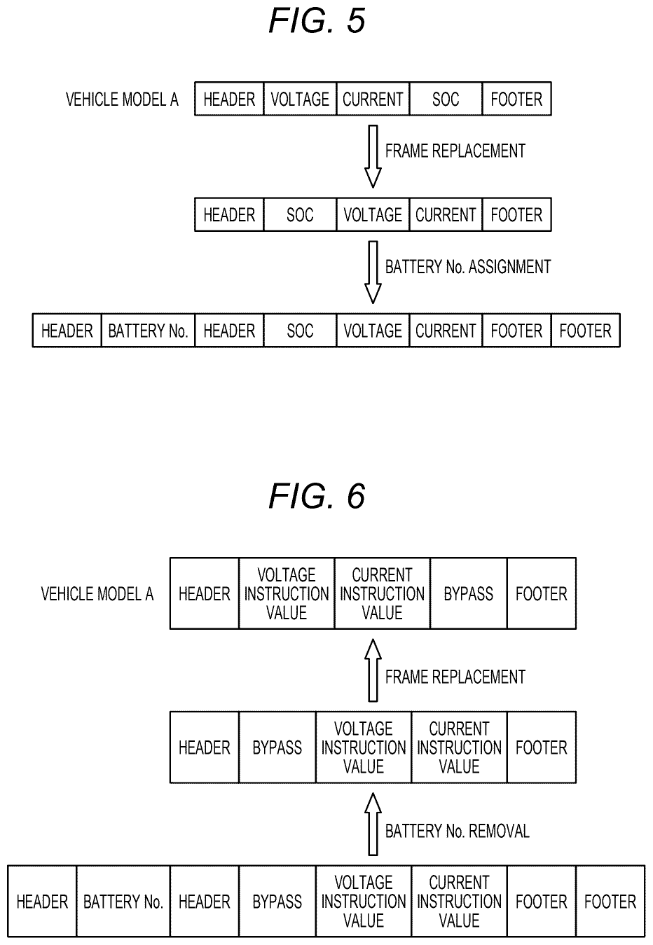

FIGS. 5 and 6 are diagrams illustrating an example of a procedure for replacing an order of a plurality of types of serial data in a frame and assigning battery No. information to the frame. As illustrated in FIG. 5, in each of the frame replacement devices 101-1 to 101-n (see FIG. 1), the order of the plurality of types of battery state information in the frame is replaced with the above predetermined order in which the BMS 10 can handle.

On the other hand, as illustrated in FIG. 6, in each of the frame replacement devices 101-1 to 101-n (see FIG. 1), the order of the plurality of types of battery control information in the frame is replaced from the above predetermined order in which the BMS 10 can handle to an order in which each of the battery modules BM1 to BMn can handle.

Here, as illustrated in FIG. 5, the serial data transmitted from the batteries B1 to Bn is not assigned with identifiers for identifying the batteries B1 to Bn. Therefore, in the present embodiment, the battery No. assignment unit 101B (see FIG. 2) assigns a battery No. to the frame including the plurality of types of serial data arranged in the above predetermined order. Specifically, the battery No. assignment unit 101B adds a header, a battery No., and a footer to the frame including the header, the plurality of types of serial data after being replaced in the predetermined order, and the footer.

On the other hand, as illustrated in FIG. 6, the battery modules BM1 to BMn cannot handle the frame of the serial data including the battery No. Therefore, in the present embodiment, the battery No. assignment unit 101B removes the battery No. from the frame that includes the battery No. and the plurality of types of serial data transmitted from the BMS 10. Specifically, the battery No. assignment unit 101B removes the header, the battery No., and the footer from the frame including the plurality of types of serial data arranged in the above predetermined order, the battery No., and the like.

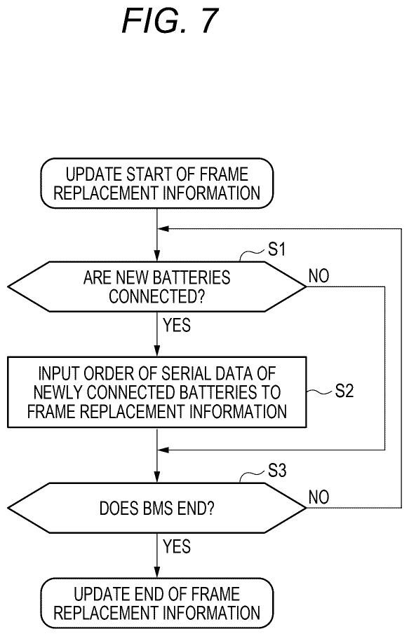

FIG. 7 is a flowchart illustrating an example of a procedure for updating the frame replacement information 101C. The frame replacement information 101C illustrated in this flowchart is updated when new batteries B1 to Bn are connected to the power storage system 1.

First, in step S1, the frame replacement processing unit 101D determines whether the new batteries B1 to Bn are connected to the power storage system 1 based on whether the serial data is received from the battery modules BM1 to BMn. If the determination is yes in step S1, the process proceeds to step S2, and if the determination is no in step S1, the process proceeds to step S3.

In step S2, an operator manually inputs the frame information, particularly the order of the serial data, corresponding to the newly connected batteries B1 to Bn from the frame information input unit 102 to the frame replacement information 101C. The frame information includes the order of the plurality of types of battery state information in the frame and the order of the battery control information in the frame. Accordingly, every time the batteries B1 to Bn are newly connected, the frame replacement information 101C is updated.

The above process in steps S1 and S2 is repeated while the BMS 10 is operating (NO in step S3), and ends together with the end of the operation of the BMS 10 (YES in step S3).

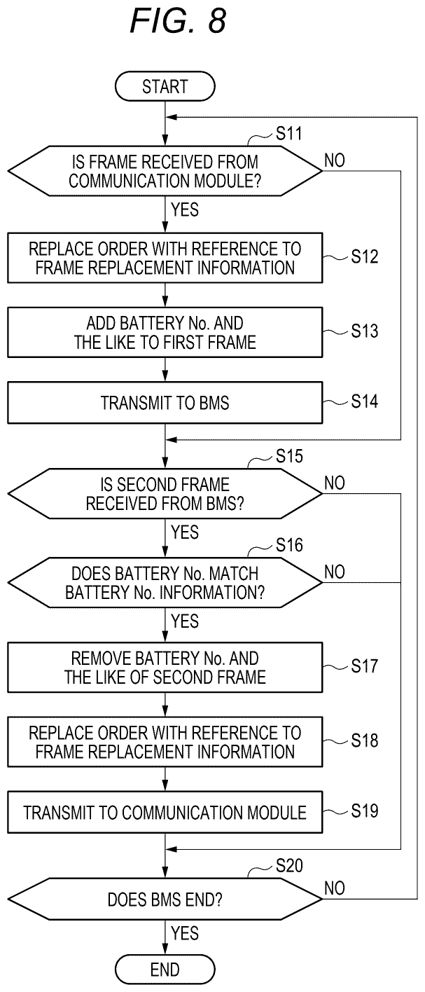

FIG. 8 is a flowchart illustrating communication between the batteries B1 to Bn and the BMS 10. The process illustrated in the flowchart is started together with the start of operation of the BMS 10.

First, in step S11, the frame replacement processing unit 101D determines whether the frame including the battery state information is received from the communication module 13. If the determination is yes in step S11, the process proceeds to step S12, and if the determination is no in step S11, the process proceeds to step S15.

In step S12, the frame replacement processing unit 101D replaces the order of the plurality of types of battery state information received from the communication module 13 with the above predetermined order with reference to the frame replacement information 101C. Next, in step S13, the battery No. assignment unit 101B adds a header, a battery No., and a footer to a first frame including a plurality of types of battery state information after being replaced in the above predetermined order. Next, in step S14, the battery No. assignment unit 101B transmits, to the BMS 10, the header, the battery No., the first frame, and the footer.

Next, in step S15, the battery No. assignment unit 101B determines whether a second frame including a plurality of types of battery control information and a battery No. is received from the BMS 10. If the determination is yes in step S15, the process proceeds to step S16, and if the determination is no in step S15, the process proceeds to step S20.

In step S16, the battery No. assignment unit 101B determines whether the battery No. assigned to the received second frame matches stored battery No. information 101E. If the determination is yes in step S16, the process proceeds to step S17, and if the determination is no in step S16, the process proceeds to step S20.

In step S17, the battery No. assignment unit 101B removes the header, the battery No., and the footer of the second frame received from the BMS 10. Next, in step S18, the frame replacement processing unit 101D replaces the order of the plurality of types of battery control information from the above predetermined order to the order in which each of the battery modules BM1 to Bn can handle with reference to the frame replacement information 101C. Next, in step S19, the frame replacement processing unit 101D transmits the frame including the plurality of types of battery control information after the order is replaced to the communication module 13 of each of the battery modules BM1 to BMn.

The above process in steps S11 and S19 is repeated while the BMS 10 is operating (NO in step S20), and ends together with the end of the operation of the BMS 10 (YES in step S20).

As described above, the communication device 100 of the present embodiment includes the frame replacement devices 101-1 to 101-n. These frame replacement devices 101-1 to 101-n first transmit frames each including a plurality of types of battery state information from the batteries B1 to Bn. Next, the frame replacement devices 101-1 to 101-n execute a frame replacement process and a battery No. assignment process. In the frame replacement process, the frame replacement devices 101-1 to 101-n replace the orders of the plurality of types of battery state information in the frames transmitted from the batteries B1 to Bn in the predetermined order common to the other frames. In addition, in the battery No. assignment process, the frame replacement devices 101-1 to 101-n assign battery Nos. for identifying the batteries B1 to Bn to the frames in which the orders of the plurality of types of battery state information are replaced with the above predetermined order. Then, the frame replacement devices 101-1 to 101-n replace the orders of the plurality of types of battery state information with the above predetermined order, and transmit, to the BMS 10, the frames to which the battery Nos. are assigned.

Accordingly, even when different types of frames in which the orders of the plurality of types of battery state information are different from one another are transmitted from the batteries B1 to Bn, the orders of the plurality of types of battery state information of all the frames match one another in the frame replacement devices 101-1 to 101-n. Accordingly, even when the power storage system 1 is implemented by using the batteries B1 to Bn for different vehicle models, the BMS 10 can acquire the plurality of types of battery state information transmitted from the batteries B1 to Bn via serial communication. Then, the BMS 10 can identify which of the batteries B1 to Bn the acquired plurality of types of battery state information corresponds to with reference to the battery No. assigned to the frame.

The communication device 100 of the present embodiment executes a process of transmitting the battery control information from the BMS 10 to the batteries B1 to Bn via serial communication. In this process, each of the frame replacement devices 101-1 to 101-n first transmits the frame including the plurality of types of battery control information and the battery No. from the BMS 10. Next, each of the frame replacement devices 101-1 to 101-n executes a battery No. removal process and a frame replacement process. In the battery No. removal process, each of the frame replacement devices 101-1 to 101-n removes the battery No. from the frame transmitted from the BMS 10. In addition, in the frame replacement process, each of the frame replacement devices 101-1 to 101-n replaces the order of the plurality of types of battery control information in the frame from which the battery No. is removed with an order defined for each of the batteries B1 to Bn. Then, each of the frame replacement devices 101-1 to 101-n transmits, to each of the batteries B1 to Bn, the frame from which the battery No. is removed and the order of the plurality of types of battery control information is replaced with the order defined for each of the batteries B1 to Bn.

Accordingly, even when the order of the plurality of types of battery control information in the frame transmitted from the BMS 10 does not match the order defined for each of the batteries B1 to Bn, the two types of order match each other in the frame replacement devices 101-1 to 101-n. In addition, in the frame replacement devices 101-1 to 101-n, after the battery No. is removed, the frames each including the plurality of types of battery control information are transmitted to the batteries B1 to Bn. Therefore, even when the power storage system 1 is implemented by using the batteries B1 to Bn for different vehicle models, the plurality of types of battery control information transmitted from the BMS 10 can be acquired by the communication modules 13 on the batteries B1 to Bn.

Further, the communication device 100 of the present embodiment can update the frame replacement information 101C. Therefore, it is possible to cope with an increase or decrease in the number of batteries B1 to Bn in the power storage system 1.

Although the present invention has been described above based on the above embodiments, the present invention is not limited to the above embodiments. Modifications may be made without departing from the gist of the present invention, or publicly known or well-known techniques may be appropriately combined.

For example, in the above embodiments, a storage battery is a battery, and the storage battery may be another secondary battery such as a capacitor. In addition, in the above embodiments, a serial communication frame including a header, serial data, and a footer is taken as an example, but it is not essential that the header or the footer is included.

Further, in the above embodiments, the frame replacement information 101C is updated at a timing when the batteries B1 to Bn are newly connected. However, the connection of the new batteries B1 to Bn may be confirmed at predetermined time intervals, and the frame replacement information 101C may be updated when the connection is confirmed.

Although various embodiments have been described above, it is needless to say that the present invention is not limited to these examples. It is apparent that those skilled in the art can come up with various modifications or corrections within the scope of the claims, and it is understood that the modifications or corrections naturally fall within the technical scope of the present invention. In addition, components described in the above embodiments may be combined freely without departing from the spirit of the invention.

The present application is based on a Japanese patent application (No. 2023-30008) filed on Feb. 28, 2023, the contents of which are incorporated herein by reference.

### REFERENCE SIGNS LIST

1: power storage system
10: BMS (state monitoring device)
100: communication device
B1 to Bn: battery (storage battery)

1. A communication device that is provided in a power storage system including a plurality of storage batteries and a state monitoring device configured to monitor states of the plurality of storage batteries based on state information that is information about the states of the storage batteries transmitted from the storage batteries, and that executes a state information transmission process of transmitting a plurality of types of the state information from the storage batteries to the state monitoring device via serial communication, wherein
the state information transmission process includes:
a process of transmitting a first frame including the plurality of types of state information from the storage batteries;
a process of replacing an order of the plurality of types of state information in the first frame transmitted from the storage batteries with a predetermined order common to other first frames;
a process of assigning storage battery identification information for identifying the storage batteries to the first frame in which the order of the plurality of types of state information is replaced with the predetermined order; and
a process of transmitting, to the state monitoring device, the first frame in which the order of the plurality of types of state information is replaced with the predetermined order and to which the storage battery identification information is assigned.

2. The communication device according to claim 1, which executes a control information transmission process of transmitting control information, which is information about the control of the storage batteries, from the state monitoring device to the storage batteries via serial communication, wherein
the control information transmission process includes:
a process of transmitting a second frame including a plurality of types of the control information and the storage battery identification information from the state monitoring device;
a process of removing the storage battery identification information from the second frame transmitted from the state monitoring device;
a process of replacing an order of the plurality of types of control information in the second frame from which the storage battery identification information is removed with an order defined for each of the storage batteries; and
a process of transmitting, to the storage batteries, the second frame from which the storage battery identification information is removed and in which the order of the plurality of types of control information is replaced with the order defined for each of the storage batteries.

3. A communication method for transmitting, in a power storage system including a plurality of storage batteries and a state monitoring device configured to monitor states of the plurality of storage batteries based on state information that is information about the states of the storage batteries transmitted from the storage batteries, a plurality of types of the state information from the storage batteries to the state monitoring device via serial communication, the communication method comprising:
a step of transmitting a frame including the plurality of types of state information from the storage batteries;
a step of replacing an order of the plurality of types of state information in the frame transmitted from the storage batteries with a predetermined order common to other frames;
a step of assigning storage battery identification information for identifying the storage batteries to the frame in which the order of the plurality of types of state information is replaced with the predetermined order; and
a step of transmitting, to the state monitoring device, the frame in which the order of the plurality of types of state information is replaced with the predetermined order and to which the storage battery identification information is assigned.

4. A power storage system comprising:
a plurality of storage batteries;
a state monitoring device configured to monitor states of the plurality of storage batteries based on state information that is information about the states of the storage batteries transmitted from the storage batteries; and
a communication device configured to transmit a plurality of types of the state information from the storage batteries to the state monitoring device via serial communication, wherein
the communication device is configured to execute:
a process of transmitting a frame including the plurality of types of state information from the storage batteries;
a process of replacing an order of the plurality of types of state information in the frame transmitted from the storage batteries with a predetermined order common to other frames;
a process of assigning storage battery identification information for identifying the storage batteries to the frame in which the order of the plurality of types of state information is replaced with the predetermined order, and
a process of transmitting, to the state monitoring device, the frame in which the order of the plurality of types of state information is replaced with the predetermined order and to which the storage battery identification information is assigned.
